(19) United States
(12) Patent Application Publication
(10) Pub. No.: US 2012/0132249 A1
(43) Pub. Date: May 31, 2012

(54) SOLAR MODULE WITH A CONNECTING UNIT HAVING A MOLDED PART

(75) Inventors: Jan Purucker, Wildau (DE); Patrick Guettler, Werder/Havel (DE)

(73) Assignee: SOLON SE, Berlin (DE)

(21) Appl. No.: 13/304,721

(22) Filed: Nov. 28, 2011

(30) Foreign Application Priority Data
Nov. 29, 2010 (DE) 10 2010 053 151

(51) Int. Cl. H01L 31/05

(52) U.S. Cl. 136/244

(57) ABSTRACT

A solar module configured for electrical connection via a solar cable includes at least one connecting unit having at least one electrically conductive connection between the solar cable and a conductive strip configured to connect a plurality of solar cells in the solar module to one another in an electrically conductive manner. The at least one connecting unit includes a bendable molded part configured to receive the at least one electrically conductive connection, a section of the solar cable and a section of the conductive strip. A bendable laminate encloses the plurality of solar cells and the conductive strip. The bendable laminate further encloses the molded part with a positive-fit. The molded part has a bendability corresponding to a bendability of the laminate.

### CROSS-REFERENCE TO PRIOR APPLICATION

Priority is claimed to German Patent Application No. DE 10 2010 053 151, filed on Nov. 29, 2010, the entire disclosure of which is hereby incorporated by reference herein.

### FIELD

The invention relates to a solar module with at least one connecting unit, and to a molded part for use in the connecting unit in the solar module.

### BACKGROUND

Solar modules consist of a multiplicity of solar cells, the contacts of which are connected in series by means of cell connectors. A plurality of rows of solar cells are then generally electrically conductively connected by means of cross connectors, so the solar module can provide a utilisable output voltage or a utilisable output current. Cell connectors and cross connectors can also be termed a conductive strip. The connection of a solar module to the consumer or to further solar modules takes place by means of two solar cables. Each solar cable is contacted to a conductive strip via an electrically conductive connection, so that the circuit is closed and current can flow in the solar cells in the event of incident sunlight. The electrical connection between solar cable and conductive strip takes place in a connecting unit. In this case, in addition to the function of contacting, the connecting unit is also always assigned the task of the tension relief of solar cables and conductive strips so that the electrically conductive connections also hold securely. Conventionally, a solar module has exactly one connecting unit, in which two solar cables are electrically conductively connected to two conductive strips. Depending on the type and application of the solar module, this can (preferably) have one connecting unit or two connecting units positioned at different points. These are generally constructed with two poles (electrically conductive plus pole connection, solar cable/conductive strip and electrically conductive minus pole connection, solar cable/conductive strip), but can also be constructed with one pole (plus pole or minus pole).

A laminated solar module is described in DE 10 2007 052 722 A1, in which connecting units in the form of flexurally resistant sockets are integrated in an electrically insulated manner into a frame surrounding the solar module. In this case, the frame is also used in particular for increasing the flexural resistance of the solar module, however, so that the connecting units are not subjected to any deflections. A flexurally resistant socket for solar modules, which is stuck onto the solar module with a base body, is likewise described in DE 10 2007 023 210 B3. The solar cables are fixedly connected to the socket by injection overmolding of the housing. The conductive strips are introduced from below into the socket. A flexurally resistant socket in which a connector pin is cast into the socket base is additionally described in DE 10 2009 053 018 A1. The socket itself is stuck onto a solar panel. Particularly in the case of solar modules which are flexible in the sense of bendable, there are problems continually with the design of the connecting unit and particularly with its connection to the bendable solar module.

DE 10 2009 039 370 A1 describes a solar module with solar cells and conductive strips which are enclosed into a bendable laminate. The connecting unit provided in the form of a socket is of multi-part construction and consists of a cross connector, a socket and a housing. The housing has cable connections for connecting to the solar cables. In this case, the cable connections take on the function of tension relief of the connecting unit with respect to the solar cables. Furthermore, the socket has connecting elements for producing electrically conductive connections between the conductive strips or the cross connector and the solar cables. The cross connector is constructed as a flat component into which at least two ends of conductive strips are cast and can be contacted by means of a socket via openings towards the top side. The flat component is arranged on a first laminate film, on which the solar cells and the conductive strips are also arranged. The flat component is not however, like the solar cells and the conductive strips, enclosed into the laminate by a further laminate film. Rather, the further laminate film has an opening in the region of the flat component, so that the flat component in the laminate remains accessible from above, is connected to the socket there and thereabove is closed off by the housing. In this case, the housing is sealed with respect to the first laminate film. The bendability of the laminate is substantially compensated by a sheet of glass, which is provided, in spite of which shifts between the bendable laminate and the rigid connecting unit and damage at the laminate or leaks at the connecting unit caused thereby can result, in particular during the production, the transport and the mounting of the solar modules.

### SUMMARY

In an embodiment, the present invention provides a solar module configured for electrical connection via a solar cable. The solar module includes at least one connecting unit having at least one electrically conductive connection between the solar cable and a conductive strip configured to connect a plurality of solar cells in the solar module to one another in an electrically conductive manner. The at least one connecting unit includes a bendable molded part configured to receive the at least one electrically conductive connection, a section of the solar cable and a section of the conductive strip. A bendable laminate encloses the plurality of solar cells and the conductive strip. The bendable laminate further encloses the molded part with a positive-fit. The molded part has a bendability corresponding to a bendability of the laminate.

### BRIEF DESCRIPTION OF THE DRAWINGS

The present invention will be described in even greater detail below based on the exemplary figures which are not to scale. The invention is not limited to the exemplary embodiments. Other features and advantages of various embodiments of the present invention will become apparent by reading the following detailed description with reference to the attached drawings which illustrate the following:

FIG. 1 shows a cross section of the solar module,

FIGS. 2A, B show a perspective view of the molded part in a first design variant,

FIG. 3 shows a perspective view of the molded part in a second design variant,

FIGS. 4A, B show two cross sections of the solar module with the molded part in a third design variant and

FIG. 5 shows a perspective view onto the solar module.

### DETAILED DESCRIPTION

In an embodiment, the present invention provides a solar module configured in the region of its connecting units in such a manner that damage at the bendable laminate or leaks at the connecting unit reliably do not occur at any point in time of the lifetime of the solar module.

In an embodiment, the present invention provides a solar module with at least one connecting unit having at least one electrically conductive connection between a solar cable used for the electrical connection of the solar module and a conductive strip connecting a plurality of solar cells in the solar module to one another in an electrically conductive manner, wherein the solar cells and the conductive strip are enclosed into a bendable laminate, and a molded part for use in the connecting unit in the solar module.

In the case of the generic solar module, according to an embodiment of the invention, the connecting unit has a bendable molded part which accommodates the at least one electrically conductive connection, a section of the solar cable and a further section of the conductive strip, which in each case connect to the at least one electrically conductive connection. In this case, the bendability of the molded part is adapted to the bendability of the laminate, that is to say deflections, to which the laminate is subjected can also be executed to the same degree by the molded part. The laminate and the molded part are equally bendable. In addition, the molded part is enclosed into the laminate in a positive-fitting manner according to the invention. Due to the bendability of the laminated molded part, damage, for example cracks, shifts or breaks, both at the laminate or the solar cells and conductive strips and at the connecting unit are prevented. The solar module can therefore in particular be transported and mounted without it being possible for deflections of the solar module occurring in the process to cause damage in the region of the connecting unit. Known connecting units are flexurally resistant and break in the case of bending of the solar module. Due to the enclosure into the laminate, there are no longer any sealing problems for the moisture-sensitive connecting unit. Complicated sealing elements are avoided. Furthermore, the connecting unit is reliably electrically insulated with respect to the environment by the electrically insulating laminate. Also, a good tension relief of the connecting unit is achieved by the solar cables, which are used for the external attachment of the solar module, by means of the molded part enclosed and therefore well anchored into the laminate in a positive-fitting manner. Furthermore, by means of the integration of the connecting unit or the molded part into the laminating process, additional work steps, such as for example placing and sealing sockets outside of the laminate, can be dispensed with.

In addition to a simplification of the production process, a reduction of the process time by means of small standing times, particularly for molding adhesive, also results.

Preferably, the molded part has a flat underside as bearing surface in the solar module. As a result, the molded part can be simply laid onto the same laminate film (or onto a module film on the laminate film), onto which the solar cells and the conductive strips are also laid. For better fixing, an adhesive layer or a laminating layer can advantageously be provided on the flat underside of the molded part. By means of the adhesive layer, a secure fixing of the molded part can be achieved before the fixing. By means of the laminating layer, it can be ensured that the molded part is reliably laminated, particularly even if the upper and the lower laminating layer do not meet, but rather end at the edge of the solar module and edge sealing is taken on by a frame element. The channels of the solar cables in particular constitute possible leak points for the solar module. These are avoided reliably if the molded part has a laminating layer in the region of the slots, which forms an intimate connection with the lower laminating film during melting. After the electrical contacting of the connecting unit with the conductive strips, a further laminate film is then laid over all elements. In a single work step, the two laminate films then weld to one another under the action of heat and enclose all intermediate elements in a dust- and water-tight manner.

The connecting unit in the invention can preferably be realised in three different embodiments. In the first embodiment, it is advantageously preferred if the molded part has a flat underside and has at least one slot incorporated into the same, into which slot, the at least one electrically conductive connection, the section of the solar cable and the section of the conductive strip are inserted. By means of the lamination, the molded part is then pressed against the solar module, so that solar cable and conductive strip are securely held. The incorporated slot can have precisely the width and thickness of solar cable and conductive strip. In the region of the conductive strip, the slot can however also be wider, so that a plurality of conductive strips can be accommodated in a common slot. If solar cable and conductive strip are inserted flush into the molded part, the same can also rest flush by means of its flat underside on the subsurface and fix the solar cable well. The molded part therefore has the functions of a housing and a tension relief in the connecting unit, particularly in the first embodiment. Solar cable, conductive strip and the at least one electrically conductive connection are arranged on a module film or on a laminate film and are spanned by the molded part and securely fixed by the common lamination. The at least one electrical connection between solar cable and conductive strip is produced before the laying of the molded part. When applying the second laminate film, all elements are then hot sealed in a dust- and water-tight manner. As the molded part in the connecting unit is also assigned the task of tension relief in interaction with the positive-fitting mechanical connection to the laminate, it is advantageous if the solar cable is held particularly fixedly. This can advantageously be achieved in that the molded part in the region of the solar cable has hold-down devices that extend into the slot, with which the solar cable is pressed onto the solar module. Preferably, the hold-down devices can be ribs running transversely to the slot, by means of which ribs, the contact pressure onto the solar cable against the solar module is increased further.

In a second preferred advantageous embodiment of the connecting unit, the molded part fixedly surrounds the section of the solar cable on one side. Thus, the molded part and the solar cable together form a common connecting component which can be accordingly prefabricated and made available and can simplify the mounting process on the solar module. A good tension relief is ensured by means of the fixed connection between solar cable and molded part. On its other side, the molded part furthermore has a flat underside, into which at least one slot, into which the further section of the conductive strip is inserted, is incorporated. The common connecting component made up of molded part and solar cable is therefore correspondingly placed onto the conductive strip during the mounting. So that, following the placing of the molded part between the solar cable and the conductive strip, the at least one electrically conductive connection can be produced, the molded part has a cavity which can be accessed from an upper side of the molded part and extends as far as the underside of the molded part. The at least one electrically conductive connection is then arranged in this cavity in the molded part. Preferably, the cavity can be closed off on the upper side of the molded part by a cover which is covered by laminate. The laminate therefore takes on the sealing function in turn. For the case that the cavity must be made accessible in the mounted state of the solar module, the laminated cover can be removed however and subsequently be stuck in again in a sealing manner.

In a third preferred advantageous embodiment of the connecting unit, the molded part preferably surrounds the section of the solar cable, the at least one electrically conductive connection and a conductive strip contact. Thus, the molded part, the solar cable and the conductive strip contact together likewise form a common connecting component. Now, in addition to the solar cable, this also contains the at least one electrically conductive connection between the solar cable and a conductive strip contact and the conductive strip contact. A good tension relief is ensured by means of the fixed mechanical connection between solar cable and molded part in this embodiment also. There is no cavity in the interior of the molded part. The electrical connection to the solar cable is prefabricated and securely enclosed in the molded part. This connecting component can also be prefabricated and thus facilitates the mounting process of the solar module.

The conductive strip contact integrated into the molded part can preferably be an additional conductive strip section which is guided out of the molded part via the flat underside and then electrically conductively connected to the conductive strip on the solar module. In this case, the electrically conductive connection of this additional conductive strip section to the conductive strip in the solar module is considerably easier to produce than the electrically conductive connection of the conductive strip to the solar cable. Here, contacts are required, which connect the conductors with round cross-section in the solar cable to the flat profile of the conductive strip. This electrically conductive connection is however already contained in the common connecting component and thus externally prefabricated. The additional conductive strip section protruding out of the underside of the molded part can also be pulled through the module film, on which the solar cells are arranged, and then be electrically conductively connected to the conductive strip by means of simple soldering, adhesive bonding or by means of a cold clamping connection. It can however also be contacted above the module film, which depends in detail on the predetermined space and geometry conditions in the solar module. Alternatively, the conductive strip contact can also be constructed as a contact plate which is arranged in the flat underside of the molded part and has cutting or spring contacts for contacting with the conductive strip. Cold contacting of this type can be produced particularly easily by simply placing the molded part. Here also, the conductive strip can either be contacted again below the module film in turn, then the latter has an opening at the corresponding point, or the cutting contacts penetrate the module film. A contacting above the module film is likewise possible in turn. In both alternatives, the contacting with the conductive strip is preferably located below the molded part, so it is likewise reliably protected and sealed within the laminate by the molded part or a laminating layer located on its underside. If the contacting is located outside of the molded part, care must be taken that it is likewise reliably sealed into the laminate.

According to an embodiment of the invention, the molded part is laminated in a positive-fitting manner. In this case, it is advantageous if the molded part is constructed in a flat manner and can be enclosed into the laminate well. Furthermore, it is advantageous for all embodiments of the molded part, if the molded part has a first end face, by means of which the solar cable is guided out of the molded part and with which it is arranged at the edge of the solar module. As a result, it is reliably ensured that the free solar cable is not also incorporated into the laminate, but rather branches off into space. For a good positive-fitting lamination of the molded part, it is furthermore advantageous if the molded part has a second end face with a chamfer. Furthermore, it is advantageous if the upper side of the molded part has a rounding and/or grooves running transversely to the solar cable. Due to the rounding, a clean lamination without the inclusion of air and without the danger of tear formation at sharp edges can in turn be achieved. By means of the transversely running grooves, a particularly good adhesion of the molded part can additionally be achieved by means of positive fit in the laminate. In addition, the grooves improve the bendability of the molded part as a function of their depth. Shapings of this type can be particularly easily produced if the molded part is advantageously constructed as a one part injection molded part made from a plastic.

It has already been mentioned at the beginning that, depending on the requirements, one or two connecting units can be provided on the solar module. Preferred however is the embodiment in which exactly one connecting unit, with two electrically conductive connections between one solar cable and one conductive strip in each case, is provided. Furthermore, the described connecting unit with the flexible laminated molded part is particularly suitable for flexible (bendable) solar modules, in which the solar cells are constructed as thin film solar cells. Here, this can be flexible solar modules which are laminated onto roofing sheets. Transporting then takes place in rolled up form. Thus, damage does not arise in the region of the connecting unit.

In addition to its direct integration of the described molded part into the connecting unit on a solar module and thus provision of the molded part only in the frame of the solar module as a whole, the molded part can, particularly in its three different embodiments as tension relief (first design variant), as component connecting to the solar cable (second design variant) or as a component connecting to the solar cable, the electrically conductive connection to the solar cable and a contact piece for simple contacting of the conductive strip on the solar module (third design variant), be provided as a prefabricated assembly for particularly simple integration into any desired generic solar module. Further details of the invention are to be drawn from the following described exemplary embodiments.

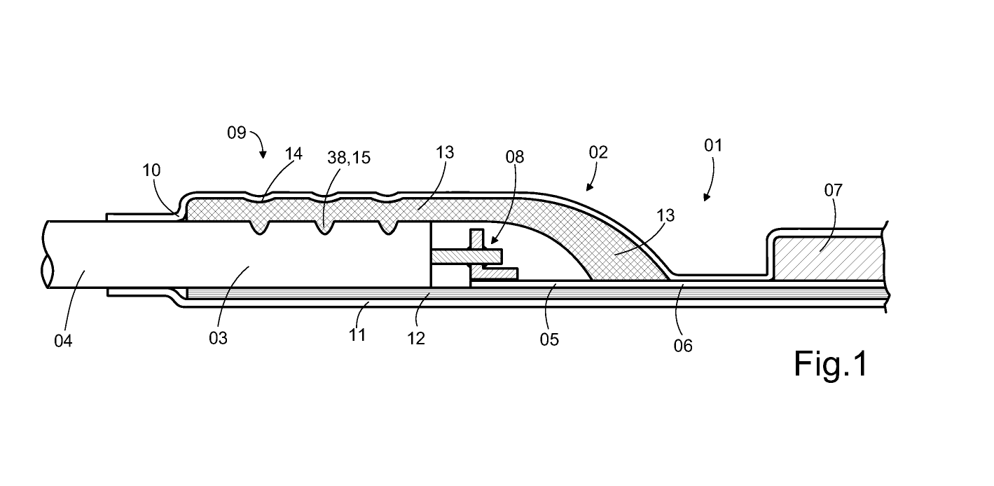

FIG. 1 shows a solar module 01 with a connecting unit 02 in cross section. The connecting unit 02 comprises a section 03 of a solar cable 04, a further section 05 of a conductive strip 06 (design as cell connector or a cross connector which electrically conductively connects a plurality of solar cells 07 in the solar module 01 to one another) and an electrically conductive connection 08 between the section 03 of the solar cable 04 and the further section 05 of the conductive strip 06. All elements are enclosed into a bendable laminate 09 in an air- and water-tight manner. The laminate 09 consists in the exemplary embodiment shown of an upper laminate film 10 and a lower laminate film 11 which are welded to one another in the edge region of the solar module 01. As a direct connection of this type is generally relatively hard to realize however, particularly in the region of the solar cable 04, the lower laminate film 11 and the upper laminate film 10 can also end at the edge of the solar module 01. The air- and water-tight connection is then taken over by a surrounding frame element. A module film 12, on which the solar cells 07 and the conductive strips 06 are arranged, is located on the lower laminate film 11.

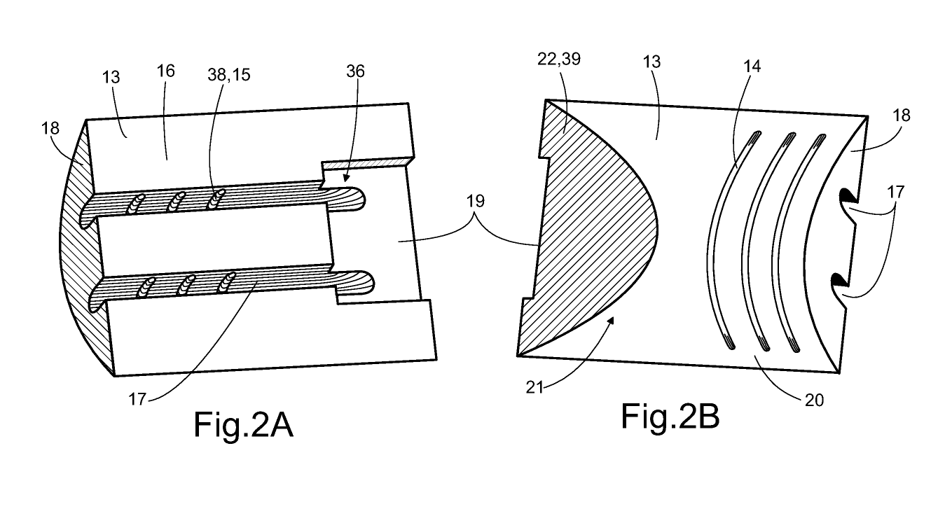

The connecting unit 02 has a bendable molded part 13 which accommodates the electrically conductive connection 08, the section 03 of the solar cable 04 and the further section 05 of the conductive strip 06. The bendable molded part 13 for example consists of a plastic and can be produced in a simple manner by molding. It is enclosed into the bendable laminate in a positive-fitting manner, wherein the bendability of the molded part 13 corresponds to the bendability of the laminate 09, so that both elements can execute the same bending under the influence of bending and do not detach from one another or become damaged. In this case, the flat construction of the molded part 13 is of particular advantage. The enclosing of the molded part 10 into the laminate 09 already ensures a good positive fit. This is increased further by the positive fit between molded part 13 and laminate 09. The positive fit is increased yet further by means of grooves 14 which are located in the upper side of the molded part 13. In addition, as a function of their depth and shaping, the grooves 14 further improve the bendability of the molded part 13, which, in addition to the material, is also achieved by its shaping and can be adapted to the bendability of the solar module 01. Furthermore, the molded part 13 has hold-down devices 38 in the form of ribs 15, with which it presses down the section 03 of the solar cable 04 onto the module film 12 and relieves possible tension on the solar cable 04. Furthermore, the molded part 13 has a flat underside 16 (see FIG. 2A) as bearing surface in the solar module 01, here on the module film 12.

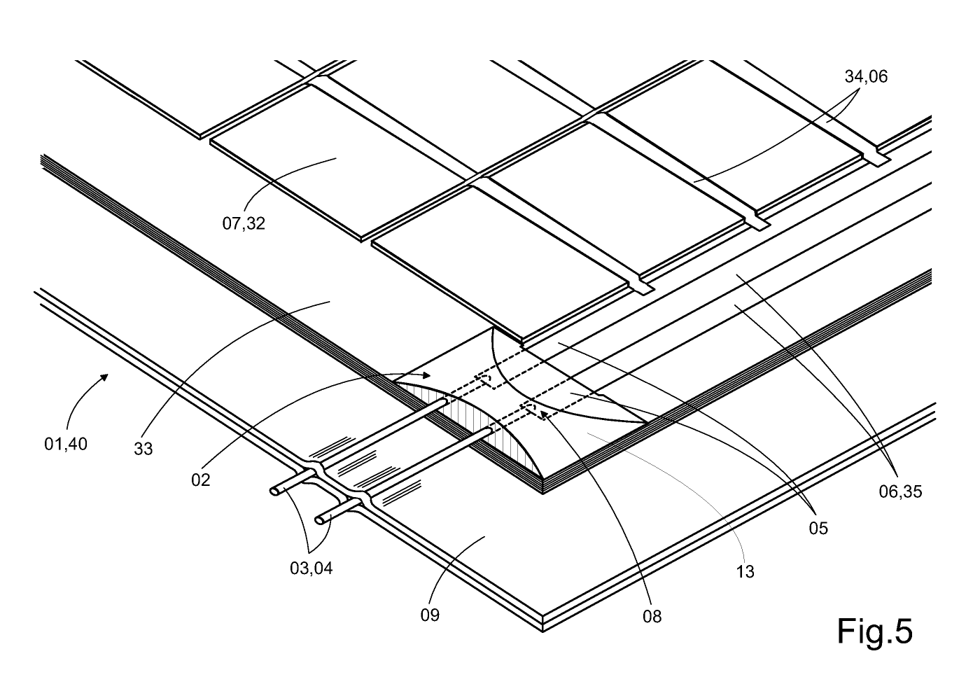

In the FIGS. 2A, 2B, the molded part 13 is illustrated perspectively from below (FIG. 2A) and from above (FIG. 2B). In the FIG. 2A, the flat underside 16 is to be seen. In the exemplary embodiment chosen, two incorporated slots 17, into which one section 03 of a solar cable 04 can be fitted in each case (see FIG. 1), are located in the underside. Hold-down devices 38 run within the slots 17, shown in the embodiment of the ribs 15. The sections 03 of the solar cable 04 are guided out through a first end face 18 of the molded part 13. Both slots 17 widen to form a common slot 19, into which the electrically conductive connection 08 and two sections 05 of two conductive strips 06 (see FIG. 1) are fitted. A continuous transition 36 between the slots 17 and the common slot 19 is to be seen. All slots 17, 19 are realised in such a manner that, following fitting of the section 03 of the solar cable 04, the electrically conductive connection 08 and the two sections 05 of the two conductive strips 06, the molded part 13 can rest flush with its flat underside 16 on the module film 12. In the FIG. 2B, an upper side 20 of the molded part 13, which has a rounding 21, is to be seen. Furthermore, a second end face 22 of the molded part 13 is illustrated, which runs with chamfers 39 and in which the common slot 19 is to be seen. The grooves 14 in the upper side 20 are also illustrated. The slots 17 end in the first end face 18 which runs vertically and can be arranged at an edge of the solar module 01, so that the solar cables 04 run outside (cf. FIG. 5).

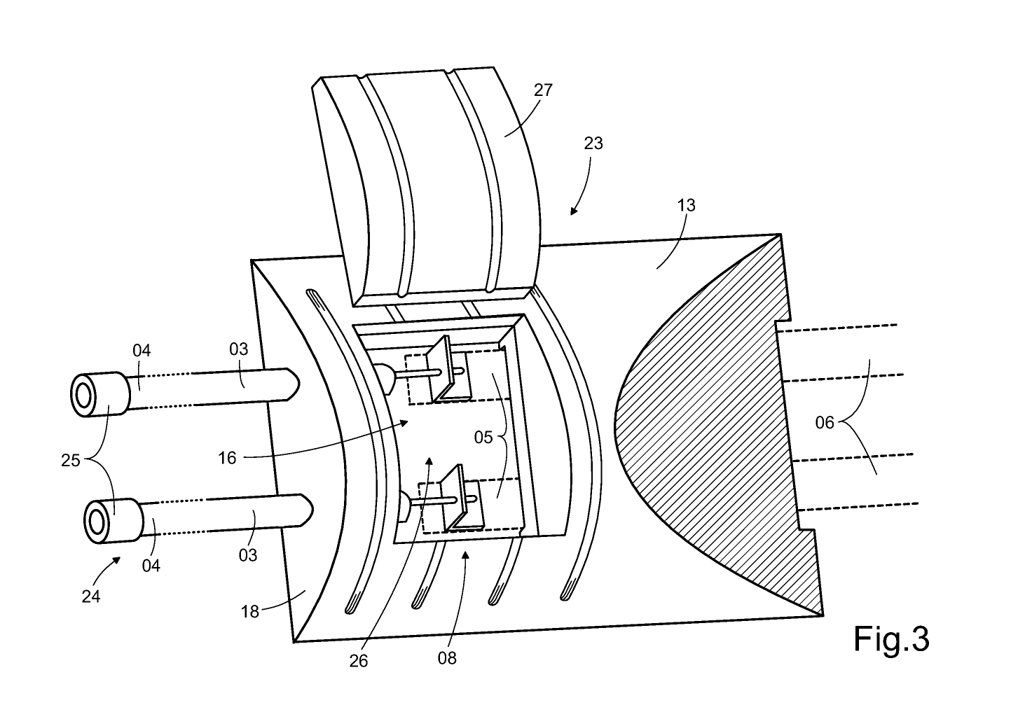

The FIG. 3 shows the molded part 13 in a permanent connection to the solar cables 04 as first common connecting component 23 in perspective plan view. On the one side, the molded part 13 permanently and fixedly surrounds the sections 03 of two solar cables 04. These are integrated into the first end face 18 and pass through the same to the outside. For connection to a next component, for example a rectifier or inverter, a battery, a further solar module 01 or the consumer, the solar cables 04 have plugs 25 on their ends 24 facing away from the molded part 13. The molded part 13 furthermore has a cavity 26 which extends from the upper side 20 of the molded part 13 to its underside 16. In this cavity 26, following the placing of the molded part 13 onto the module film 12, the electrically conductive connection 08 to the conductive strips 06 (illustrated dashed in FIG. 3) can be produced. Furthermore, in FIG. 3, a cover 27 is illustrated, which is fitted into the cavity 26 following the production of the electrically conductive connection 08 and before the lamination. Following the lamination, the cavity 26 is then closed off in a sealing manner, but not filled by the laminate 09, so the cavity 26 remains accessible if required by removing the cover 27.

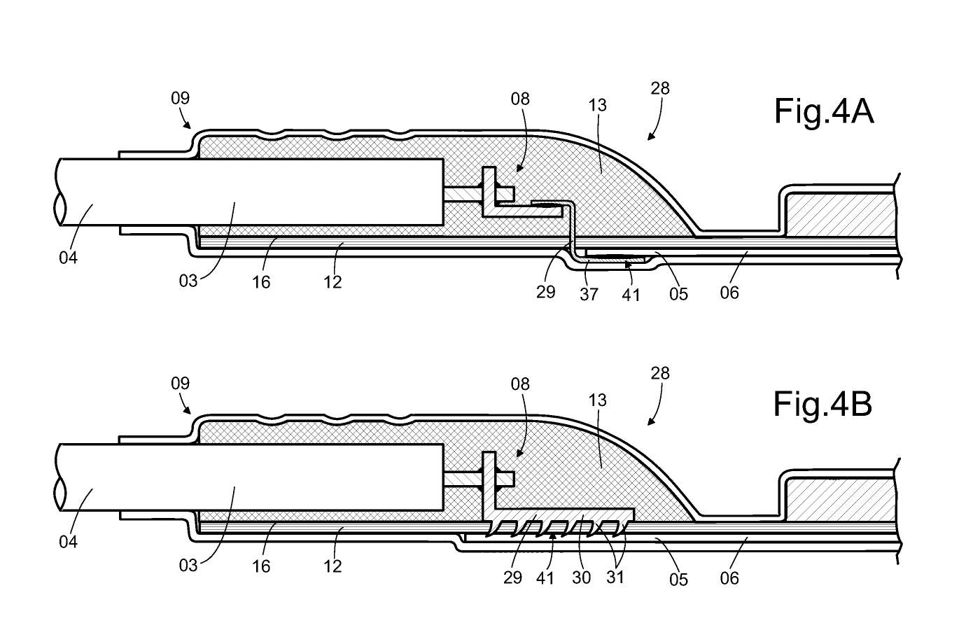

The FIGS. 4A and 4B show two embodiments of the molded part 13 in a second common connecting component 28 in the connecting unit 02 in the mounted state. In addition to the section 03 of the solar cable 04, the electrically conductive connection 08 and a conductive strip contact 29 (corresponding to two conductive strip contacts 29 in the case of a contacting 41 of two conductive strips 06) are fixedly connected to the molded part 13. Following the placing of the molded part 13 onto the module film 12 only the conductive strips 06 are still contacted. To this end, the conductive strip contact 29 according to FIG. 4A can be constructed as an additional conductive strip section 37 which is guided out of the flat underside 16 of the molded part 13. The additional conductive strip section 37 is then also guided through the module film 12 and permanently electrically contacted with the conductive strip 06 in a simple manner, for example by means of soldering. In this case, in the exemplary embodiment shown, the contacting 41 is located below the molded part 13 and is therefore permanently protected. In an arrangement of the contacting 41 outside of the molded part 13, the same is integrated into the laminate 09. Alternatively, the conductive strip contact 29 according to FIG. 4B can also be constructed as a contact plate 30 which is arranged in the flat underside 16 of the molded part 13. In the exemplary embodiment shown, the contact plate 30 has cutting contacts 31 which contact the conductive strip 06 through the module film 12 by means of simple placing of the molded part 13 onto the module film 12. Alternatively, the module film 12 can have a corresponding section, in particular if spring contacts are used on the contact plate 30. In this embodiment also, the contacting 41 is well protected by means of the molded part 13 located thereabove. The laminate 09, which encloses the molded part 13, can be seen well in both FIGS. 4A, 4B. In the FIGS. 4A, 4B, reference numbers not mentioned are to be drawn from the preceding figures.

In FIG. 5, a perspective view onto a solar module 01 is illustrated, which in the exemplary embodiment shown is a flexible solar module 40 with thin film solar cells 32 which can be laminated onto a roofing sheet. The arrangement of the connecting unit 02 with the molded part 13 in an edge region 33, so that the solar cables 04 make it outside unhindered, is to be seen. Furthermore, the transparent laminate 09, which encloses the entire solar module 01 with its components, in particular also the conductive strips 04 (cell connector 34 and cross connector 35), in an air- and water-tight manner, is to be seen. The electrically conductive connection 08 between solar cables 04 and conductive strips 06 is indicated dashed. The solar module 01 shown has exactly one connecting unit 02 which comprises two electrically conductive connections 08 between one solar cable 04 and one conductive strip 06 (cross connector 35 here) in each case. In addition to the exemplary embodiments shown, further embodiments are likewise readily implementable for the invention.

While the invention has been described with reference to particular embodiments thereof, it will be understood by those having ordinary skill the art that various changes may be made therein without departing from the scope and spirit of the invention. Further, the present invention is not limited to the embodiments described herein; reference should be had to the appended claims.

### REFERENCE LIST

01 Solar module
02 Connecting unit
03 Section of 04
04 Solar cable
05 Section of 06
06 Conductive strip
07 Solar cell
08 Electrically conductive connection
09 Laminate
10 Upper laminate film
11 Lower laminate film
12 Module film
13 Molded part
14 Groove
15 Rib
16 Flat underside of 13
17 Slot
18 First end face of 13
19 Common slot
20 Upper side of 13
21 Rounding of 20
22 Second end face of 13
23 First connecting component
24 Averted end of 04
25 Plug
26 Cavity
27 Cover
28 Second connecting component
29 Conductive strip contact
30 Contact plate
31 Cutting contacts
32 Thin film solar cell
33 Edge region of 01
34 Cell connector
35 Cross connector
36 Transition between 17, 19
37 Conductive strip section
38 Hold-down device
39 Chamfer
40 Flexible solar module
41 Contacting 29 with 05

1. A solar module configured for electrical connection via a solar cable, the solar module comprising:
at least one connecting unit including at least one electrically conductive connection between the solar cable and a conductive strip configured to connect a plurality of solar cells in the solar module to one another in an electrically conductive manner, the at least one connecting unit including a bendable molded part configured to receive the at least one electrically conductive connection, a section of the solar cable and a section of the conductive strip; and
a bendable laminate enclosing the plurality of solar cells and the conductive strip, the bendable laminate further enclosing the molded part with a positive-fit, the molded part having a bendability corresponding to a bendability of the laminate.

2. The solar module according to claim 1, wherein the molded part includes an underside having a flat bearing surface.

3. The solar module according to claim 2, wherein the molded part includes at least one slot in the underside configured to receive the at least one electrically conductive connection, the section of the solar cable and the section of the conductive strip.

4. The solar module according to claim 3, wherein the molded part includes hold-down devices in a region of the section of the solar cable having ribs which run transversely to the at least one slot and configured to press down the section of the solar cable.

5. The solar module according to claim 2, wherein the molded part fixedly surrounds the section of the solar cable on a first side and includes at least one common slot disposed in the underside on a second side, the at least one common slot being configured to receive the section of the conductive strip, and wherein the at least one electrically conductive connection is disposed in a cavity extending from an upper side to the underside of the molded part, the cavity being closed off on the upper side of the molded part by a cover which is covered by the laminate.

6. The solar module according to claim 1, wherein the molded part fixedly surrounds the section of the solar cable, the at least one electrically conductive connection and a conductive strip contact which is electrically conductively connected to the at least one electrically conductive connection and to the conductive strip.

7. The solar module according to claim 6, wherein the conductive strip contact includes an additional conductive strip section which is extends out of a flat underside of the molded part.

8. The solar module according to claim 6, wherein the conductive strip contact includes a contact plate disposed in a flat underside of the molded part and at least one of cutting contacts and spring contacts configured to contact the conductive strip.

9. The solar module according to claim 1, wherein the molded part includes a first end face disposed in an end region of the solar module and configured to guide the section of the solar cable out of the molded part.

10. The solar module according to claim 9, wherein the solar module includes a second end face having a chamfer.

11. The solar module according to claim 1, wherein an upper side of the molded part includes at least one of a rounding and grooves running transversely to the section of the solar cable.

12. The solar module according to claim 2, wherein the underside of the molded part includes at least one of an adhesive layer and a laminating layer.

13. The solar module according to claim 1, wherein the molded part is formed in one piece as a plastic injected molded part.

14. The solar module according to claim 1, wherein the at least one electrically conductive connection includes two electrically conductive connections, each of which connect between a respective solar cable and a respective conductive strip.

15. The solar module according to claim 1, wherein the at least one connecting unit is disposed in an edge region of the solar module.
